(19) United States
(12) Patent Application Publication
(10) Pub. No.: US 2026/0114197 A1
(43) Pub. Date: Apr. 23, 2026

(54) PROCESSING METHODS TO IMPROVE ETCHED SILICON-AND-GERMANIUM-CONTAINING MATERIAL SURFACE PROPERTIES

(71) Applicant: Applied Materials, Inc., Santa Clara, CA (US)

(72) Inventors: Bin Yao, Santa Clara, CA (US); Zihui Li, Santa Clara, CA (US); Chang-Yi Tsai, Santa Clara, CA (US); Jiayin Huang, Fremont, CA (US); Chia-Ling Kao, San Jose, CA (US); Anchuan Wang, San Jose, CA (US)

(73) Assignee: Applied Materials, Inc., Santa Clara, CA (US)

(21) Appl. No.: 18/919,172

(22) Filed: Oct. 17, 2024

(51) Int. Cl. H01L 21/3065; H01J 37/32

(52) U.S. Cl. CPC H10P 50/242; H01J 37/32449; H01J 37/32091; H01J 2237/334

(57) ABSTRACT

Exemplary semiconductor processing methods may include providing a fluorine-containing precursor and a nitrogen-containing precursor to a processing region of a semiconductor processing chamber. A substrate may be housed within the processing region. Alternating layers of silicon-and-germanium-containing material and silicon-containing material may be disposed on the substrate. The methods may include forming plasma effluents of the fluorine-containing precursor and the nitrogen-containing precursor. The methods may include contacting the substrate with the plasma effluents of the fluorine-containing precursor and the nitrogen-containing precursor. The contacting may selectively remove a portion of the silicon-and-germanium-containing material.

### TECHNICAL FIELD

The present technology relates to semiconductor processes and equipment. More specifically, the present technology relates to etching silicon-and-germanium-containing material in vertical structures.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include providing a fluorine-containing precursor and a nitrogen-containing precursor to a processing region of a semiconductor processing chamber. A substrate may be housed within the processing region. Alternating layers of silicon-and-germanium-containing material and silicon-containing material may be disposed on the substrate. The methods may include forming plasma effluents of the fluorine-containing precursor and the nitrogen-containing precursor. The methods may include contacting the substrate with the plasma effluents of the fluorine-containing precursor and the nitrogen-containing precursor. The contacting may selectively remove a portion of the silicon-and-germanium-containing material.

In some embodiments, the fluorine-containing precursor may be or include nitrogen trifluoride (NF₃). The nitrogen-containing precursor may be or include diatomic nitrogen (N₂). The plasma effluents of the fluorine-containing precursor and the nitrogen-containing precursor may be capacitively coupled plasma (CCP) effluents. The plasma effluents of the fluorine-containing precursor and the nitrogen-containing precursor may be formed at a plasma power of less than or about 1,000 W. The silicon-containing material may be or include silicon. A flow rate ratio of the nitrogen-containing precursor relative to the fluorine-containing precursor may be greater than or about 2:1. A temperature within the semiconductor processing chamber may be maintained at less than or about 100° C. A pressure within the semiconductor processing chamber may be maintained at less than or about 10 Torr. The silicon-and-germanium-containing material may be removed relative to the silicon-containing material at a selectivity of greater than or about 1.5:1. Subsequent to removing the portion of the silicon-and-germanium-containing material, a 3σ average surface roughness (Rₐ) of the silicon-and-germanium-containing material may be less than or about 5 nm.

Some embodiments of the present technology may encompass semiconductor processing methods. The methods may include providing a fluorine-containing precursor and diatomic nitrogen (N2) to a processing region of a semiconductor processing chamber. A substrate may be housed within the processing region. Alternating layers of silicon-and-germanium-containing material and silicon-containing material may be disposed on the substrate. The methods may include forming capacitively coupled plasma (CCP) effluents of the fluorine-containing precursor and N₂. The methods may include contacting the substrate with the CCP effluents of the fluorine-containing precursor and N₂. The contacting may selectively remove a portion of the silicon-and-germanium-containing material. A temperature within the semiconductor processing chamber may be maintained at less than or about 100° C.

In some embodiments, the fluorine-containing precursor may be or include nitrogen trifluoride (NF₃). A flow rate ratio of N₂ relative to NF₃ may be greater than or about 10:1. The CCP effluents of the fluorine-containing precursor and N₂ may be formed at a plasma power of less than or about 500 W. A temperature within the semiconductor processing chamber may be maintained at less than or about 50° C. A pressure within the semiconductor processing chamber may be maintained at less than or about 7 Torr.

Some embodiments of the present technology may encompass semiconductor processing methods. The methods may include etching a portion of a silicon-and-germanium-containing material from a substrate disposed within a processing region of a semiconductor processing chamber. The silicon-and-germanium-containing material may be one material of one or more alternating layers of material on the substrate. The silicon-and-germanium-containing material may be characterized by a first average surface roughness (Rₐ). The methods may include, subsequent to etching the silicon-and-germanium-containing material, providing a fluorine-containing precursor and a nitrogen-containing precursor to the processing region of the semiconductor processing chamber. The methods may include forming plasma effluents of the fluorine-containing precursor and the nitrogen-containing precursor. The methods may include contacting the substrate with the plasma effluents of the fluorine-containing precursor and the nitrogen-containing precursor. The contacting may remove an additional portion of the silicon-and-germanium-containing material.

In some embodiments, the methods may include performing a dry etch prior to etching the portion of the silicon-and-germanium-containing material. Subsequent to removing the portion of the silicon-and-germanium-containing material, the average surface roughness (Rₐ) of the silicon-and-germanium-containing material may be improved by greater than or about 10% relative to the first average surface roughness (Rₐ).

Such technology may provide numerous benefits over conventional systems and techniques. For example, the processes may remove silicon-and-germanium-containing material in an alternating stack of materials with reduced footing. Additionally, the processes may remove silicon-and-germanium-containing material in an alternating stack of materials with reduced roughness, such as line width roughness (LWR), and/or with reduced rounding. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

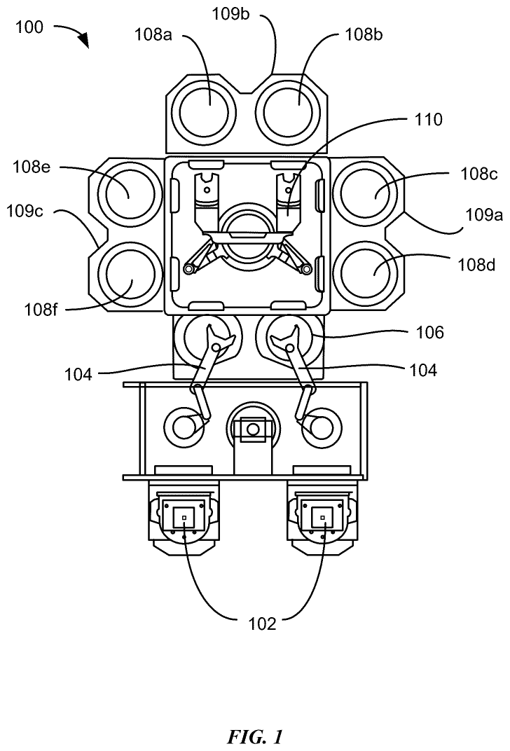

FIG. 1 shows a top plan view of one embodiment of an exemplary processing system according to embodiments of the present technology.

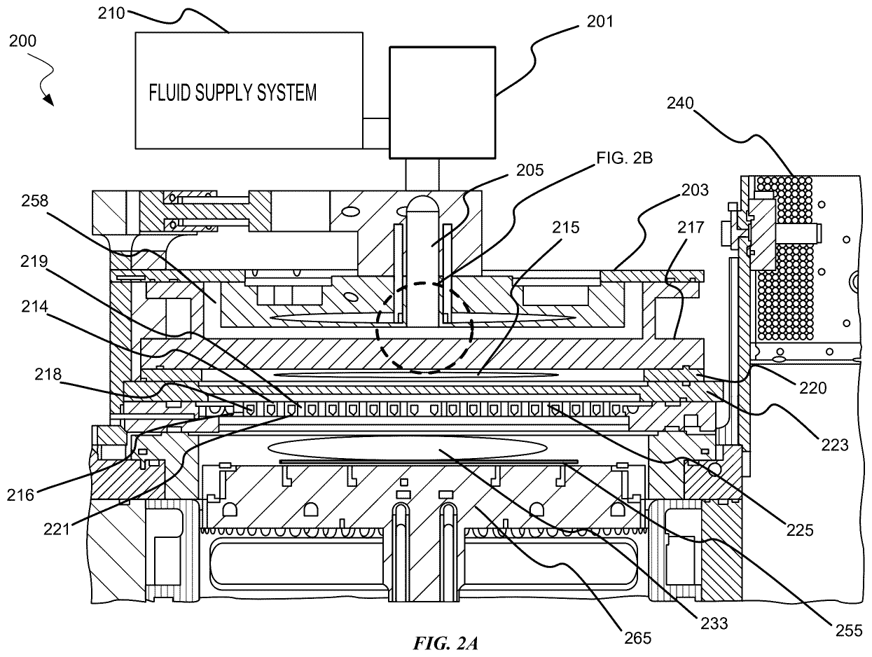

FIG. 2A shows a schematic cross-sectional view of an exemplary processing chamber according to embodiments of the present technology.

FIG. 2B shows a detailed view of a portion of the processing chamber illustrated in FIG. 2A according to embodiments of the present technology.

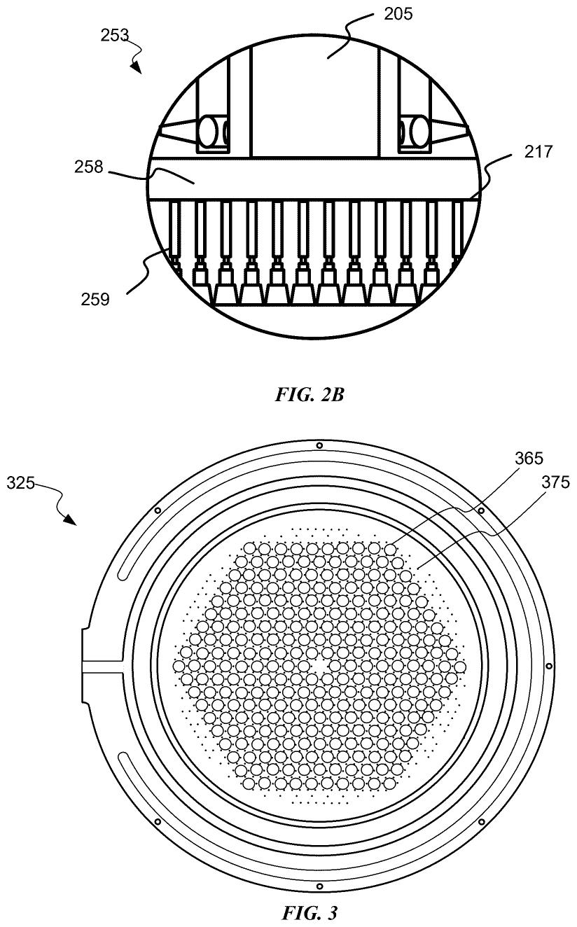

FIG. 3 shows a bottom plan view of an exemplary showerhead according to embodiments of the present technology.

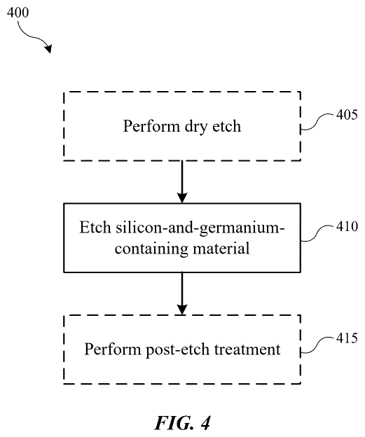

FIG. 4 shows exemplary operations in a method according to embodiments of the present technology.

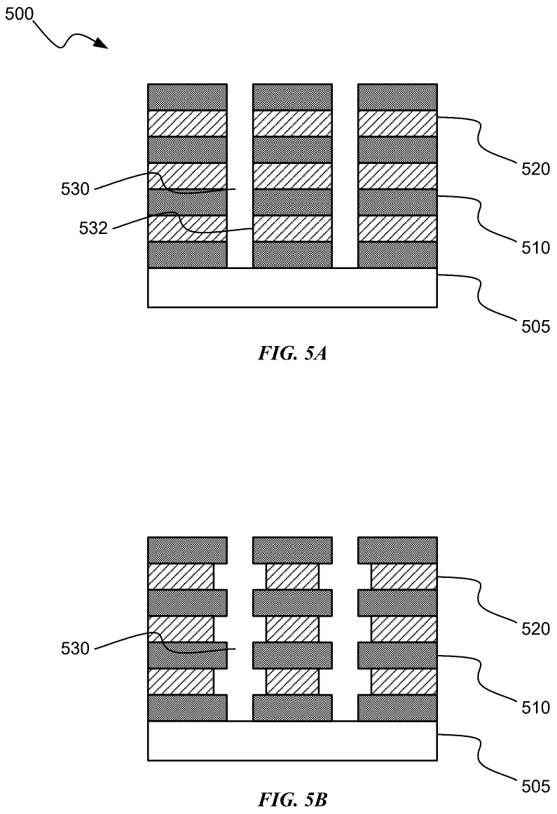

FIGS. 5A-5B show cross-sectional views of substrates being processed according to embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning to gate-all-around (GAA) transistors, many process operations are modified from more conventional fin field-effect (FinFET) transistors. Additionally, as structures continue to reduce in size, the thicknesses of material layers reduce and the aspect ratios of memory holes and other structures increase, sometimes dramatically.

During GAA processing, alternating layers of material are deposited on a substrate, such as alternating layers of silicon-containing material and silicon-and-germanium-containing material. In forming the transistor, memory holes or trenches may be formed through the alternating layers of material. During GAA processing, the silicon-and-germanium-containing material may be recessed from within the memory holes or trenches at one or more stages of processing, such as to form material that will serve as nanowires/nanosheets.

Because of the high aspect ratios of these memory holes or trenches, as well as the layers of material defining the memory holes or trenches, conventional technologies may struggle to uniformly recess the silicon-and-germanium-containing material. For example, intermixing layers, or interfaces between the silicon-and-germanium-containing material and adjacent layers, such as silicon-containing material, may not etch as uniformly as a bulk portion of the silicon-and-germanium-containing material. This non-uniform etching may result in footing or rounding of the silicon-and-germanium-containing material. Additionally, the presence of residue, such as impurities in the silicon-and-germanium-containing material, may serve as a mask material that results in increased surface roughness of the silicon-and-germanium-containing material after etching.

The present technology overcomes these issues by performing an etch operation using a capacitively coupled plasma (CCP). The CCP effluents may uniformly etch the silicon-and-germanium-containing material, relative to adjacent material, such that the silicon-and-germanium-containing material may be characterized by a substantially square etch front. Additionally, the present technology may include a post-etch treatment. The post-etch treatment may reduce surface roughness of the silicon-and-germanium-containing material as well as reduce rounding of the silicon-and-germanium-containing material. By using the etch operation with CCP effluents and/or the post-etch treatment, profile issues associated with footing, roughness, and/or rounding may be addressed. Thus, the etched and/or treated silicon-and-germanium-containing material may be characterized by an improved profile or etch front compared to conventional technologies, which may result in transistors, such as GAA transistors, with improved efficiency.

Although the remaining disclosure will routinely identify specific etching processes utilizing the disclosed technology, it will be readily understood that the systems and methods are equally applicable to etching processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the operations described.

FIG. 1 shows a top plan view of one embodiment of a processing system 100 of deposition, etching, baking, and curing chambers according to embodiments. In the figure, a pair of front opening unified pods (FOUPs) 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

The substrate processing chambers 108a-f may include one or more system components for depositing, annealing, curing and/or etching a dielectric film on the substrate wafer. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to etch a dielectric film on the substrate. Any one or more of the processes described may be carried out in chamber(s) separated from the fabrication system shown in different embodiments. It will be appreciated that additional configurations of deposition, etching, annealing, and curing chambers for dielectric films are contemplated by system 100.

FIG. 2A shows a cross-sectional view of an exemplary process chamber system 200 with partitioned plasma generation regions within the processing chamber. During film etching, e.g., titanium nitride, tantalum nitride, tungsten, silicon, polysilicon, silicon oxide, silicon nitride, silicon oxynitride, silicon oxycarbide, etc., a process gas may be flowed into the first plasma region 215 through a gas inlet assembly 205. A remote plasma system (RPS) 201 may optionally be included in the system, and may process a first gas which then travels through gas inlet assembly 205. The inlet assembly 205 may include two or more distinct gas supply channels where the second channel (not shown) may bypass the RPS 201, if included.

A cooling plate 203, faceplate 217, ion suppressor 223, showerhead 225, and a substrate support 265, having a substrate 255 disposed thereon, are shown and may each be included according to embodiments. The pedestal 265 may have a heat exchange channel through which a heat exchange fluid flows to control the temperature of the substrate, which may be operated to heat and/or cool the substrate or wafer during processing operations. The wafer support platter of the pedestal 265, which may comprise aluminum, ceramic, or a combination thereof, may also be resistively heated in order to achieve relatively high temperatures, such as from up to or about 100° C. to above or about 1100° C., using an embedded resistive heater element.

The faceplate 217 may be pyramidal, conical, or of another similar structure with a narrow top portion expanding to a wide bottom portion. The faceplate 217 may additionally be flat as shown and include a plurality of through-channels used to distribute process gases. Plasma generating gases and/or plasma excited species, depending on use of the RPS 201, may pass through a plurality of holes, shown in FIG. 2B, in faceplate 217 for a more uniform delivery into the first plasma region 215.

Exemplary configurations may include having the gas inlet assembly 205 open into a gas supply region 258 partitioned from the first plasma region 215 by faceplate 217 so that the gases/species flow through the holes in the faceplate 217 into the first plasma region 215. Structural and operational features may be selected to prevent significant backflow of plasma from the first plasma region 215 back into the supply region 258, gas inlet assembly 205, and fluid supply system 210. The faceplate 217, or a conductive top portion of the chamber, and showerhead 225 are shown with an insulating ring 220 located between the features, which allows an AC potential to be applied to the faceplate 217 relative to showerhead 225 and/or ion suppressor 223. The insulating ring 220 may be positioned between the faceplate 217 and the showerhead 225 and/or ion suppressor 223 enabling a capacitively coupled plasma (CCP) to be formed in the first plasma region. A baffle (not shown) may additionally be located in the first plasma region 215, or otherwise coupled with gas inlet assembly 205, to affect the flow of fluid into the region through gas inlet assembly 205.

The ion suppressor 223 may comprise a plate or other geometry that defines a plurality of apertures throughout the structure that are configured to suppress the migration of ionically-charged species out of the first plasma region 215 while allowing uncharged neutral or radical species to pass through the ion suppressor 223 into an activated gas delivery region between the suppressor and the showerhead. In embodiments, the ion suppressor 223 may comprise a perforated plate with a variety of aperture configurations. These uncharged species may include highly reactive species that are transported with less reactive carrier gas through the apertures. As noted above, the migration of ionic species through the holes may be reduced, and in some instances completely suppressed. Controlling the amount of ionic species passing through the ion suppressor 223 may advantageously provide increased control over the gas mixture brought into contact with the underlying wafer substrate, which in turn may increase control of the deposition and/or etch characteristics of the gas mixture. For example, adjustments in the ion concentration of the gas mixture can significantly alter its etch selectivity, e.g., SiGeₓ:SiOₓ etch ratios, SiGeₓ:Si etch ratios, etc. In alternative embodiments in which deposition is performed, it can also shift the balance of conformal-to-flowable style depositions for dielectric materials.

The plurality of apertures in the ion suppressor 223 may be configured to control the passage of the activated gas, i.e., the ionic, radical, and/or neutral species, through the ion suppressor 223. For example, the aspect ratio of the holes, or the hole diameter to length, and/or the geometry of the holes may be controlled so that the flow of ionically-charged species in the activated gas passing through the ion suppressor 223 is reduced. The holes in the ion suppressor 223 may include a tapered portion that faces the plasma excitation region 215, and a cylindrical portion that faces the showerhead 225. The cylindrical portion may be shaped and dimensioned to control the flow of ionic species passing to the showerhead 225. An adjustable electrical bias may also be applied to the ion suppressor 223 as an additional means to control the flow of ionic species through the suppressor.

The ion suppressor 223 may function to reduce or eliminate the amount of ionically charged species traveling from the plasma generation region to the substrate. Uncharged neutral and radical species may still pass through the openings in the ion suppressor to react with the substrate. It should be noted that the complete elimination of ionically charged species in the reaction region surrounding the substrate may not be performed in embodiments. In certain instances, ionic species are intended to reach the substrate in order to perform the etch and/or deposition process. In these instances, the ion suppressor may help to control the concentration of ionic species in the reaction region at a level that assists the process.

Showerhead 225 in combination with ion suppressor 223 may allow a plasma present in first plasma region 215 to avoid directly exciting gases in substrate processing region 233, while still allowing excited species to travel from chamber plasma region 215 into substrate processing region 233. In this way, the chamber may be configured to prevent the plasma from contacting a substrate 255 being etched. This may advantageously protect a variety of intricate structures and films patterned on the substrate, which may be damaged, dislocated, or otherwise warped if directly contacted by a generated plasma. Additionally, when plasma is allowed to contact the substrate or approach the substrate level, the rate at which materials may be etched increase. Accordingly, an exposed region of material may be further protected by maintaining the plasma remotely from the substrate.

The processing system may further include a power supply 240 electrically coupled with the processing chamber to provide electric power to the faceplate 217, ion suppressor 223, showerhead 225, and/or pedestal 265 to generate a plasma in the first plasma region 215 or processing region 233. The power supply may be configured to deliver an adjustable amount of power to the chamber depending on the process performed. Such a configuration may allow for a tunable plasma to be used in the processes being performed. Unlike a remote plasma unit, which is often presented with on or off functionality, a tunable plasma may be configured to deliver a specific amount of power to the plasma region 215. This in turn may allow development of particular plasma characteristics such that precursors may be dissociated in specific ways to enhance the etching profiles produced by these precursors.

A plasma may be ignited either in chamber plasma region 215 above showerhead 225 or substrate processing region 233 below showerhead 225. Plasma may be present in chamber plasma region 215 to produce the radical precursors from an inflow of, for example, a fluorine-containing precursor or other precursor. An AC voltage typically in the radio frequency (RF) range may be applied between the conductive top portion of the processing chamber, such as faceplate 217, and showerhead 225 and/or ion suppressor 223 to ignite a plasma in chamber plasma region 215 during deposition. An RF power supply may generate a high RF frequency of 13.56 MHz but may also generate other frequencies alone or in combination with the 13.56 MHz frequency.

FIG. 2B shows a detailed view 253 of the features affecting the processing gas distribution through faceplate 217. As shown in FIGS. 2A and 2B, faceplate 217, cooling plate 203, and gas inlet assembly 205 intersect to define a gas supply region 258 into which process gases may be delivered from gas inlet 205. The gases may fill the gas supply region 258 and flow to first plasma region 215 through apertures 259 in faceplate 217. The apertures 259 may be configured to direct flow in a substantially unidirectional manner such that process gases may flow into processing region 233, but may be partially or fully prevented from backflow into the gas supply region 258 after traversing the faceplate 217.

The gas distribution assemblies such as showerhead 225 for use in the processing chamber section 200 may be referred to as dual channel showerheads (DCSH) and are additionally detailed in the embodiments described in FIG. 3. The dual channel showerhead may provide for etching processes that allow for separation of etchants outside of the processing region 233 to provide limited interaction with chamber components and each other prior to being delivered into the processing region.

The showerhead 225 may comprise an upper plate 214 and a lower plate 216. The plates may be coupled with one another to define a volume 218 between the plates. The coupling of the plates may be so as to provide first fluid channels 219 through the upper and lower plates, and second fluid channels 221 through the lower plate 216. The formed channels may be configured to provide fluid access from the volume 218 through the lower plate 216 via second fluid channels 221 alone, and the first fluid channels 219 may be fluidly isolated from the volume 218 between the plates and the second fluid channels 221. The volume 218 may be fluidly accessible through a side of the gas distribution assembly 225.

FIG. 3 is a bottom view of a showerhead 325 for use with a processing chamber according to embodiments. Showerhead 325 may correspond with the showerhead 225 shown in FIG. 2A. Through-holes 365, which show a view of first fluid channels 219, may have a plurality of shapes and configurations in order to control and affect the flow of precursors through the showerhead 225. Small holes 375, which show a view of second fluid channels 221, may be distributed substantially evenly over the surface of the showerhead, even amongst the through-holes 365, and may help to provide more even mixing of the precursors as they exit the showerhead than other configurations.

The chambers discussed previously may be used in performing exemplary methods including etching methods. Turning to FIG. 4 is shown exemplary operations in a method 400 according to embodiments of the present technology. Prior to the first operation of the method 400, a substrate may be processed in one or more ways before being placed within a processing region of a chamber in which method 400 may be performed. For example, alternating layers of material may be formed on the substrate and then one or more memory holes or trenches may be formed through the alternating layers. The alternating layers may include any number of materials, and may include alternating layers of a silicon-containing material, such as silicon or silicon-and-oxygen-containing material, and a silicon-and-germanium-containing material. Although the remaining disclosure will discuss silicon-containing material and silicon-and-germanium-containing material, any other known materials used in these two layers may be substituted for one or more of the layers. Additionally, prior to the first operation of method 400, a native oxide may be removed from one or more materials disposed on the substrate. Some or all of these operations may be performed in chambers or system tools as previously described, or may be performed in different chambers on the same system tool, which may include the chamber in which the operations of method 400 are performed.

The diameter or width of exemplary memory holes or trenches may be a few tens of nanometers or less, while the height of the memory holes or trenches may be on the order or a few microns or more. This may produce aspect ratios or height to width ratios of greater than or about 5:1, and may be greater than or about 10:1, greater than or about 15:1, greater than or about 20:1, greater than or about 50:1, greater than or about 75:1, greater than or about 100:1, or even greater. The present technology may be applied to, for example, memory applications, to GAA transistors, and to logic applications. Accordingly, in embodiments over 2 layers, over 3 layers, over 4 layers, over 5 layers, over 10 layers, over 15 layers, over 20 layers, over 25 layers, over 50 layers, over 75 layers, or over one hundred layers of alternating layers of material may be present within each memory hole trench.

Method 400 may include performing an etch at optional operation 405. While any etch may be performed at optional operation 405, some embodiments may include a dry etch using one or more halogen-containing precursors, inert gases, and other precursors or, if formed, plasma effluents thereof. In embodiments, the plasma effluents, if formed, may be formed as a high-frequency plasma. The etch at optional operation 405 may create a trench or feature, such as the previously discussed memory holes or trenches, into the alternating layers of material.

After the dry etch at optional operation 405, method 400 may include etching a portion of a silicon-and-germanium-containing material from the substrate at operation 410. Etching a portion of a silicon-and-germanium-containing material may include providing one or more etchant precursors to the processing region, optionally forming plasma effluents of the one or more etchant precursors, and contacting the substrate, including the silicon-and-germanium-containing material, with the precursors or plasma effluents thereof. The contacting may remove the portion of the silicon-and-germanium-containing material.

The precursors provided at operation 410 may include one or more halogen-containing precursors. Additional precursors, such as a hydrogen-containing precursor, a nitrogen-containing precursor, or other useful precursors may also be provided. In embodiments, the halogen-containing precursor may be, for example, a fluorine-containing precursor. Exemplary fluorine-containing precursor may be or include, but are not limited to, atomic fluorine (F), diatomic fluorine (F₂), nitrogen trifluoride (NF₃), sulfur tetrafluoride (SF₄), sulfur hexafluoride (SF₆), carbon tetrafluoride (CF₄), tungsten hexafluoride (WF₆), xenon difluoride (XeF₂), as well as various other fluorine-containing precursors used or useful in semiconductor processing. Exemplary hydrogen-containing precursors may be or include, but are not limited to, hydrocarbons, such as diatomic hydrogen (H₂), ammonia (NH₃), water or steam (H₂O), diimide (N₂H₂), hydrazine (N₂H₄), as well as various other hydrogen-containing precursors used or useful in semiconductor processing. Exemplary nitrogen-containing precursors may be or include, but are not limited to, hydrocarbons, such as diatomic nitrogen (N₂), NH₃, N₂O, NO₂, N₂H₂, N₂H₄, as well as various other nitrogen-containing precursors used or useful in semiconductor processing. In one non-limiting example, the halogen-containing precursor may be NF₃ and the nitrogen-containing precursor may be N₂. Carrier gases may also be provided with the halogen-containing precursor and one or more secondary precursors. The carrier gases, which may be inert gases, such as argon (Ar), helium (He), or other inert gases, may be provided to help control uniformity, particle distribution, and/or pressure.

In embodiments, a flow rate ratio of the nitrogen-containing precursor relative to the halogen-containing precursor may be greater than or about 2:1. By using both the nitrogen-containing precursor and the halogen-containing precursor, such as at the discussed flow rate ratios, an increased amount of NF-based and NF₂-based radicals may be formed. The increased amount of NF-based and NF₂-based radicals may increase the concentration of F-based radicals while also reducing recombination of F radicals to molecular F₂. As an example, the selectivity of plasma-enhanced NF₃ may be lower than F₂, so the selectivity of etching silicon-and-germanium-containing material versus silicon-containing material, such as silicon, may be decreased after adding N₂. To achieve the reaction equilibrium and generate the noticeable performance improvement (e.g., reduced silicon-and-germanium-containing material footing, surface roughness, and rounding), an increased amount of the nitrogen-containing precursor may be needed. Accordingly, the flow rate ratio of the nitrogen-containing precursor relative to the halogen-containing precursor may be greater than or about 3:1, and may be greater than or about 4:1, greater than or about 5:1, greater than or about 10:1, greater than or about 20:1, greater than or about 30:1, greater than or about 40:1, greater than or about 50:1, greater than or about 75:1, greater than or about 100:1, greater than or about 150:1, greater than or about 200:1, greater than or about 250:1, greater than or about 300:1, greater than or about 350:1, greater than or about 400:1, greater than or about 500:1, or more.

A flow rate of the halogen-containing precursor may be sufficient to provide adequate etching of the silicon-and-germanium-containing material. In embodiments, a flow rate of the halogen-containing precursor may be greater than or about 0.1 sccm, and may be greater than or about 0.2 sccm, greater than or about 0.3 sccm, greater than or about 0.4 sccm, greater than or about 0.5 sccm, greater than or about 0.6 sccm, greater than or about 0.7 sccm, greater than or about 0.8 sccm, greater than or about 0.9 sccm, greater than or about 1 sccm, greater than or about 2 sccm, greater than or about 3 sccm, greater than or about 4 sccm, greater than or about 5 sccm, greater than or about 6 sccm, greater than or about 7 sccm, greater than or about 8 sccm, greater than or about 9 sccm, greater than or about 10 sccm, or higher. However, to maintain precise control over the etch by slowing the etch rate, the flow rate of the halogen-containing precursor may be less than or about 50 sccm, and may be less than or about 40 sccm, less than or about 30 sccm, less than or about 20 sccm, less than or about 15 sccm, less than or about 10 sccm, less than or about 9 sccm, less than or about 8 sccm, less than or about 7 sccm, less than or about 6 sccm, less than or about 5 sccm, less than or about 4 sccm, less than or about 3 sccm, less than or about 2 sccm, less than or about 1 sccm, or less.

A flow rate of the nitrogen-containing precursor may be sufficient to provide adequate distribution of the halogen-containing precursor and may also dilute the halogen-containing precursor. In embodiments, a flow rate of the nitrogen-containing precursor may be greater than or about 0.1 sccm, and may be greater than or about 10 sccm, greater than or about 20 sccm, greater than or about 30 sccm, greater than or about 40 sccm, greater than or about 50 sccm, greater than or about 60 sccm, greater than or about 70 sccm, greater than or about 80 sccm, greater than or about 90 sccm, greater than or about 100 sccm, greater than or about 125 sccm, greater than or about 150 sccm, greater than or about 200 sccm, greater than or about 300 sccm, greater than or about 400 sccm, greater than or about 500 sccm, or higher.

As previously discussed, plasma effluents of the precursors may be optionally formed. In embodiments, the plasma effluents, such as plasma effluents of the fluorine-containing precursor and the nitrogen-containing precursor, may be capacitively coupled plasma (CCP) effluents. The plasma effluents of the precursors, if present, may be generated at a plasma power of less than or about 1,000 W, and may be generated at less than or about 750 W, less than or about 500 W, less than or about 400 W, less than or about 300 W, less than or about 250 W, less than or about 200 W, less than or about 150 W, less than or about 100 W, less than or about 75 W, less than or about 50 W, less than or about 45 W, less than or about 40 W, less than or about 35 W, less than or about 30 W, less than or about 25 W, less than or about 20 W, less than or about 15 W, or less. By generating the plasma effluents at a reduced plasma power, dissociation may be reduced and precise control of the etch rate and amount of etched silicon-and-germanium-containing material may be maintained.

As previously discussed, method 400 may include contacting the substrate, including the silicon-and-germanium-containing material, with the precursors or plasma effluents thereof at operation 410. The contacting may remove the portion of the silicon-and-germanium-containing material. In embodiments, the contacting may selectively remove the portion of the silicon-and-germanium-containing material relative to one or more other materials, such as silicon-containing material and/or the substrate. The etching at operation 410 may recess the silicon-and-germanium-containing material uniformly such that the silicon-and-germanium-containing material is characterized by a substantially square etch front. That is, the silicon-and-germanium-containing material may be characterized by reduced footing compared to conventional technologies. In GAA transistors, silicon-and-germanium material and silicon-containing material may be epitaxially grown alternatively to form a stack of alternating materials. Inevitably, there may be a thin transition interfacial layer with less germanium content formed between adjacent layers of silicon-and-germanium material and silicon-containing material. Etch rates of the thin transition interfacial layer with less germanium content may be different from the bulk or main silicon-and-germanium material. However, these etch rate differences can be varied or adjusted based on the precursors used. For example, although NF₃ and F₂ may both etch silicon-and-germanium material, their etch rates may vary. NF₃ may have exhibit lower selectivity between silicon-and-germanium material and silicon-containing material than F₂. In the present embodiments, the halogen-containing precursor, such as NF₃, may decouple into F radicals when plasma of the halogen-containing precursor if formed. However, the F radicals may not be stable. The F radicals may easily recombine to molecular F₂. By adding the nitrogen-containing precursor, such as N₂, with the halogen-containing precursor, again such as NF₃, the F radicals may react with N₂ and form more NF-based or NF₂-based radicals, thus reducing F₂ recombination. The increased amount and concentration of F-based radicals, such NF-based or NF₂-based radicals, may better etch portions of silicon-and-germanium material where molecular F₂ cannot, such as the thin transition interfacial layer with less germanium content between adjacent layers of silicon-and-germanium material and silicon-containing material. Thus, by adding the nitrogen-containing precursor, such as N₂, with the halogen-containing precursor, such as NF₃, footing can be improved.

In embodiments, the portion of the silicon-and-germanium-containing material that is etched may be characterized by a recess, relative to adjacent layers, of greater than or about 1 angstrom (Å), and may be characterized by a recess of greater than or about 5 Å, greater than or about 1 nanometer (nm), greater than or about 2 nm, greater than or about 3 nm, greater than or about 4 nm, greater than or about 5 nm, greater than or about 10 nm, or more.

By performing the operations previously discussed, silicon-and-germanium-containing material may be removed relative to silicon-containing material at a selectivity of greater than or about 1:1, and removed at a selectivity of greater than or about 1.1:1, greater than or about 1.2:1, greater than or about 1.3:1, greater than or about 1.4:1, greater than or about 1.5:1, greater than or about 1.6:1, greater than or about 1.7:1, greater than or about 1.8:1, greater than or about 1.9:1, greater than or about 2:1, greater than or about 3:1, greater than or about 4:1, or more.

An etch rate of the silicon-and-germanium-containing material may be greater than or about 0.5 nm/second (nm/s), and may be greater than or about 0.6 nm/s, greater than or about 0.7 nm/s, greater than or about 0.75 nm/s, greater than or about 0.8 nm/s, greater than or about 0.85 nm/s, greater than or about 0.9 nm/s, greater than or about 0.95 nm/s, greater than or about 1.0 nm/s, greater than or about 1.2 nm/s, greater than or about 1.4 nm/s, greater than or about 1.6 nm/s, greater than or about 1.8 nm/s, greater than or about 2 nm/2, greater than or about 2.5 nm/s, greater than or about 3 nm/s, greater than or about 3.5 nm/s, greater than or about 4 nm/s, or more.

At optional operation 415, method 400 may include performing a post-etch treatment. The optional dry etch at optional operation 405 and silicon-and-germanium-containing material etch at operation 410 may result in material that is characterized by an excessive surface roughness and/or undesirable rounding. Residues present on the silicon-and-germanium-containing material may almost serve as mask materials that result in uneven etching of the silicon-and-germanium-containing material. Due to these residues, surface roughness of the silicon-and-germanium-containing material, subsequent etching, may be increased. Therefore, prior to optional operation 415, silicon-and-germanium-containing material is characterized by a first average surface roughness (Rₐ). In embodiments, prior to operation 415, a 3σ average surface roughness (Rₐ) of the silicon-and-germanium-containing material may be greater than or about 4.5 nm, and may be greater than or about 5 nm, greater than or about 5.5 nm, greater than or about 6 nm, greater than or about 6.5 nm, greater than or about 7 nm, greater than or about 7.5 nm, greater than or about 8 nm, greater than or about 8.5 nm, or more.

Additionally, due to interfaces that exist between the silicon-and-germanium-containing material and adjacent material, such as silicon-and-oxygen-containing material, etch rates may differ along the silicon-and-germanium-containing material. For example, a bulk portion of the silicon-and-germanium-containing material may be characterized by a higher germanium concentration than portions of the silicon-and-germanium-containing material closer to the adjacent material, such as silicon-and-oxygen-containing material. From the bulk portion of the silicon-and-germanium-containing material to the adjacent material, such as silicon-and-oxygen-containing material, the germanium concentration may decrease gradually. Thus, there may be a portion of silicon-and-germanium-containing characterized by a lower germanium concentration and a portion of germanium-and-oxygen-containing material between the bulk portion of the silicon-and-germanium-containing material and the adjacent material, such as silicon-and-oxygen-containing material. Due to the differences in etch rate, the etched silicon-and-germanium-containing material may be characterized by a concave etch front. Prior to the post-etch treatment, the silicon-and-germanium-containing material may be characterized by rounding of greater than or about 2.5 nm, and may be greater than or about 2.6 nm, greater than or about 2.7 nm, greater than or about 2.8 nm, greater than or about 2.9 nm, greater than or about 3 nm, greater than or about 3.1 nm, greater than or about 3.2 nm, greater than or about 3.3 nm, or more. Rounding may be measured by comparing a width of the silicon-and-germanium-containing material at a widest part, such as adjacent to the silicon-and-oxygen-containing material, compared to a width of the silicon-and-germanium-containing material at a narrowest part, such as a midpoint of the silicon-and-germanium-containing material between the adjacent materials.

The post-etch treatment may reduce surface roughness and/or address rounding. The post-etch treatment at optional operation 415 may include providing one or more treatment precursors to the processing region, optionally forming plasma effluents of the one or more treatment precursors, and contacting the substrate, including the silicon-and-germanium-containing material, with the treatment or plasma effluents thereof. The contacting may address the previously discussed profile issues present in the silicon-and-germanium-containing material.

The treatment precursors provided at optional operation 415 may include a halogen-containing precursor, such as a fluorine-containing precursor, and a nitrogen-containing precursor. Exemplary halogen-containing precursors and nitrogen-containing precursors may be any of the precursors previously discussed with regard to operation 410. In one non-limiting example, the halogen-containing precursor may be NF₃ and the nitrogen-containing precursor may be N₂. Similar to operation 410, carrier gases may also be provided with the treatment precursors. The carrier gases, which may be inert gases, such as argon (Ar), helium (He), or other inert gases, may be provided to help control uniformity, particle distribution, and/or pressure.

Flow rates of the halogen-containing precursor, such as a fluorine-containing precursor, and the nitrogen-containing precursor may be any of the flow rates previously discussed with regard to operation 410. Flow rate ratios of the nitrogen-containing precursor relative to the halogen-containing precursor may also be any of the flow rate ratios previously discussed with regard to operation 410. Additionally, plasma effluents of the treatment precursors may be any of the plasma powers previously discussed with regard to operation 410.

As previously discussed, method 400 may include contacting the substrate, including the silicon-and-germanium-containing material, with the treatment precursors or plasma effluents thereof at optional operation 415. The contacting may remove a portion of the silicon-and-germanium-containing material, such as an additional portion of the silicon-and-germanium-containing material compared to the portion that may have been removed at operation 410, to reduce surface roughness and/or address rounding. That is, the treatment precursors may remove the residue, or impurities, on the surface of the silicon-and-germanium-containing material to reduce the roughness. Additionally, the treatment precursors may even the etched amount of the intermixing material, or material between the bulk portion of the silicon-and-germanium-containing material and the adjacent material, to result in a more uniform and straight etch front. The halogen-containing precursor, such as NF₃, may be be decoupled into F radicals after plasma formation. However, F radicals are not stable. F radicals may recombine to form molecular F₂. By adding the nitrogen-containing precursor, such as N₂, with the halogen-containing precursor, such as NF₃, F radicals may react with N₂ and form NF-based or NF₂-based radicals, which may reduce recombination into F₂. The increased amount and concentration of F-based radicals, such as NF-based or NF₂-based radicals, may better etch areas of the silicon-and-germanium-containing material where molecular F₂ cannot, such as at an interfacial area between the silicon-and-germanium-containing material and the silicon-containing material. Thus, by adding the nitrogen-containing precursor, such as N₂, with the halogen-containing precursor, such as NF₃, both the surface roughness and rounding can be improved.

In embodiments, the average surface roughness (Rₐ) of the silicon-and-germanium-containing material may be improved by greater than or about 5%, and may be improved by greater than or about 10%, greater than or about 15%, greater than or about 20%, greater than or about 25%, greater than or about 30%, greater than or about 35%, greater than or about 40%, or more. For example, the 36 average surface roughness (Rₐ) of the silicon-and-germanium-containing material, subsequent the post-etch treatment, may be less than or about 5.5 nm, and may be less than or about 5 nm, less than or about 4.9 nm, less than or about 4.8 nm, less than or about 4.7 nm, less than or about 4.6 nm, less than or about 4.5 nm, less than or about 4.3 nm, less than or about 4.2 nm, less than or about 4.1 nm, less than or about 4 nm, less than or about 3.9 nm, less than or about 3.8 nm, less than or about 3.7 nm, less than or about 3.6 nm, less than or about 3.5 nm, or less.

Additionally, the rounding of the silicon-and-germanium-containing material may be improved by greater than or about 5%, and may be improved by greater than or about 10%, greater than or about 15%, greater than or about 20%, greater than or about 25%, or more. For example, the rounding of the silicon-and-germanium-containing material, subsequent the post-etch treatment, may be less than or about 3.5 nm, and may be less than or about 3.4 nm, less than or about 3.3 nm, less than or about 3.2 nm, less than or about 3.1 nm, less than or about 3 nm, less than or about 2.9 nm, less than or about 2.8 nm, less than or about 2.7 nm, less than or about 2.6 nm, less than or about 2.5 nm, less than or about 2.4 nm, less than or about 2.3 nm, or less.

Process conditions may also impact the operations performed in method 400 as well as other etching methods according to the present technology. Each of the operations of method 400 may be performed during a constant temperature in embodiments, while in some embodiments the temperature may be adjusted during different operations. For example, the substrate, pedestal, or chamber temperature while contacting the substrate with the plasma effluents may be maintained between about −100° C. and about 200° C. in embodiments. At higher temperatures, an etch rate of silicon-containing material may increase, which may lead to a less selective etch of silicon-and-germanium-containing material. Accordingly, the temperature may also be maintained at less than or about 200° C., and may be maintained at less than or about 180° C., less than or about 160° C., less than or about 140° C., less than or about 120° C., less than or about 100° C., less than or about 80° C., less than or about 60° C., less than or about 50° C., less than or about 40° C., less than or about 30° C., less than or about 20° C., less than or about 10° C., less than or about 0° C., less than or about −10° C., less than or about −20° C., less than or about −30° C., less than or about −40° C., less than or about −50° C., less than or about-60° C., less than or about −70° C., less than or about −80° C., less than or about −90° C., or lower. In embodiments, the temperature may also be maintained at greater than or about or about −100° C., and may be maintained at greater than or about or about −90° C., greater than or about or about −80° C., greater than or about or about −70° C., greater than or about or about −60° C., greater than or about or about −50° C., greater than or about or about −40° C., greater than or about or about −30° C., greater than or about or about −20° C., greater than or about or about −10° C., greater than or about or about 0° C., greater than or about or about 10° C., greater than or about or about 20° C., greater than or about or about 30° C., greater than or about or about 40° C., greater than or about or about 50° C., greater than or about or about 60° C., greater than or about or about 70° C., greater than or about or about 80° C., greater than or about or about 90° C., greater than or about or about 100° C., greater than or about or about 120° C., greater than or about or about 140° C., greater than or about or about 160° C., greater than or about or about 180° C., or higher.

The pressure within the chamber may also affect the operations performed, and in embodiments the pressure within the semiconductor processing chamber may be maintained at less than about 40 Torr. At higher pressures, LWR may increase. As such, the pressure within the semiconductor processing chamber may be maintained at less than or about 30 Torr, and may be maintained at less than or about 20 Torr, less than or about 10 Torr, less than or about 9 Torr, less than or about 8 Torr, less than or about 7.5 Torr, less than or about 7 Torr, less than or about 6.5 Torr, less than or about 6 Torr, less than or about 5.5 Torr, less than or about 5 Torr, less than or about 4.5 Torr, less than or about 4 Torr, less than or about 3.5 Torr, less than or about 3 Torr, less than or about 2.5 Torr, less than or about 2 Torr, less than or about 1.5 Torr, less than or about 1 Torr, less than or about 0.5 Torr, less than or about 0.3 Torr, less than or about 0.2 Torr, less than or about 0.1 Torr, or less.

Turning to FIGS. 5A-5B, cross-sectional views of structure 500 being processed according to embodiments of the present technology are illustrated. As illustrated in FIG. 5A substrate 505 may have plurality of stacked layers overlying the substrate, which may be silicon-containing material, silicon-and-germanium-containing material, or other substrate materials. The alternating layers of material may include materials suitable for GAA transistors, such as silicon-containing material 510 alternating with silicon-and-germanium-containing material 520. The silicon-and-germanium-containing material 520 may be or include material that will be recessed to produce nanowires/nanosheets in GAA transistors. Although illustrated with only 7 layers of material, exemplary structures may include any of the numbers of layers previously discussed. Memory holes or trenches 530 may be defined through the stacked structure to the level of substrate 505. Memory holes or trenches 530 may be defined by sidewalls 532 that may be composed of the alternating layers of silicon-containing material 510 and silicon-and-germanium-containing material 520.

FIG. 5B illustrates structure 500 after operations of methods according to the present technology have been performed, such as discussed with respect to FIG. 4 above. An etching operation may be performed to recess the silicon-and-germanium-containing material 520. The etching may recess a portion of the silicon-and-germanium-containing material 520, which may form nanowires/nanosheets of the silicon-and-germanium-containing material 520 useful in GAA applications between neighboring silicon-containing material 510. Substrate 505 may show minimal etching at the bottom of trenches 530. Subsequent recessing, a post-etching treatment may be performed. While not illustrated, the post-etching treatment may reduce roughness, such as LWR, as well as improve rounding of the recessed silicon-and-germanium-containing material 520.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a fluorine-containing precursor and a nitrogen-containing precursor to a processing region of a semiconductor processing chamber, wherein a substrate is housed within the processing region, and wherein alternating layers of silicon-and-germanium-containing material and silicon-containing material are disposed on the substrate;
forming plasma effluents of the fluorine-containing precursor and the nitrogen-containing precursor; and
contacting the substrate with the plasma effluents of the fluorine-containing precursor and the nitrogen-containing precursor, wherein the contacting selectively removes a portion of the silicon-and-germanium-containing material.

2. The semiconductor processing method of claim 1, wherein the fluorine-containing precursor comprises nitrogen trifluoride (NF₃).

3. The semiconductor processing method of claim 1, wherein the nitrogen-containing precursor comprises diatomic nitrogen (N₂).

4. The semiconductor processing method of claim 1, wherein the plasma effluents of the fluorine-containing precursor and the nitrogen-containing precursor are capacitively coupled plasma (CCP) effluents.

5. The semiconductor processing method of claim 1, wherein the plasma effluents of the fluorine-containing precursor and the nitrogen-containing precursor are formed at a plasma power of less than or about 1,000 W.

6. The semiconductor processing method of claim 1, wherein the silicon-containing material comprises silicon.

7. The semiconductor processing method of claim 1, wherein a flow rate ratio of the nitrogen-containing precursor relative to the fluorine-containing precursor is greater than or about 2:1.

8. The semiconductor processing method of claim 1, wherein a temperature within the semiconductor processing chamber is maintained at less than or about 100° C.

9. The semiconductor processing method of claim 1, wherein a pressure within the semiconductor processing chamber is maintained at less than or about 10 Torr.

10. The semiconductor processing method of claim 1, wherein the silicon-and-germanium-containing material is removed relative to the silicon-containing material at a selectivity of greater than or about 1.5:1.

11. The semiconductor processing method of claim 1, wherein, subsequent to removing the portion of the silicon-and-germanium-containing material, a 3σ average surface roughness (Rₐ) of the silicon-and-germanium-containing material is less than or about 5 nm.

12. A semiconductor processing method comprising:
providing a fluorine-containing precursor and diatomic nitrogen (N₂) to a processing region of a semiconductor processing chamber, wherein a substrate is housed within the processing region, wherein alternating layers of silicon-and-germanium-containing material and silicon-containing material are disposed on the substrate;
forming capacitively coupled plasma (CCP) effluents of the fluorine-containing precursor and N₂; and
contacting the substrate with the CCP effluents of the fluorine-containing precursor and N₂, wherein the contacting selectively removes a portion of the silicon-and-germanium-containing material, and wherein a temperature within the semiconductor processing chamber is maintained at less than or about 100° C.

13. The semiconductor processing method of claim 12, wherein the fluorine-containing precursor comprises nitrogen trifluoride (NF₃).

14. The semiconductor processing method of claim 13, wherein a flow rate ratio of N₂ relative to NF₃ is greater than or about 10:1.

15. The semiconductor processing method of claim 12, wherein the CCP effluents of the fluorine-containing precursor and N₂ are formed at a plasma power of less than or about 500 W.

16. The semiconductor processing method of claim 12, wherein a temperature within the semiconductor processing chamber is maintained at less than or about 50° C.

17. The semiconductor processing method of claim 12, wherein a pressure within the semiconductor processing chamber is maintained at less than or about 7 Torr.

18. A semiconductor processing method comprising:
etching a portion of a silicon-and-germanium-containing material from a substrate disposed within a processing region of a semiconductor processing chamber, wherein the silicon-and-germanium-containing material is one material of one or more alternating layers of material on the substrate, and wherein the silicon-and-germanium-containing material is characterized by a first average surface roughness (Rₐ);
subsequent to etching the silicon-and-germanium-containing material, providing a fluorine-containing precursor and a nitrogen-containing precursor to the processing region of the semiconductor processing chamber;
forming plasma effluents of the fluorine-containing precursor and the nitrogen-containing precursor; and
contacting the substrate with the plasma effluents of the fluorine-containing precursor and the nitrogen-containing precursor, wherein the contacting removes an additional portion of the silicon-and-germanium-containing material.

19. The semiconductor processing method of claim 18, further comprising:
performing a dry etch prior to etching the portion of the silicon-and-germanium-containing material.

20. The semiconductor processing method of claim 18, wherein, subsequent to removing the portion of the silicon-and-germanium-containing material, the average surface roughness (Rₐ) of the silicon-and-germanium-containing material is improved by greater than or about 10% relative to the first average surface roughness (Rₐ).
